(19) United States
(12) Patent Application Publication
(10) Pub. No.: US 2026/0058093 A1
(43) Pub. Date: Feb. 26, 2026

(54) METHOD FOR LOCALIZING A REGION OF INTEREST IN A SAMPLE AND MICROMACHINING THE SAMPLE USING A CHARGED PARTICLE BEAM

(71) Applicant: TECHNISCHE UNIVERSITEIT DELFT, Delft (NL)

(72) Inventors: Jacob Pieter HOOGENBOOM, Delft (NL); Daan Benjamin BOLTJE, Delft (NL); Ernest Benjamin VAN DER WEE, Delft (NL)

(21) Appl. No.: 19/099,511

(22) PCT Filed: Jul. 7, 2023
(86) PCT No.: PCT/NL2023/050367

§ 371 Date: Jan. 29, 2025

(30) Foreign Application Priority Data
Jul. 29, 2022 (NL) 2032640

(51) Int. Cl. H01J 37/305; G01N 21/64; G02B 21/16; G02B 21/36; H01J 37/304

(52) U.S. Cl. CPC H01J 37/3056; G01N 21/6458; G02B 21/16; G02B 21/367; H01J 37/3045; H01J 2237/31745

(57) ABSTRACT

A method and apparatus are provided for localization of a region of interest with a fluorescent entity inside a sample and for micromachining the sample in an integral fluorescence microscope/charged particle beam apparatus. The optics of the fluorescence microscope for imaging the sample onto a detector comprises an astigmatic optical component. The method comprises the steps of: determining a position of a focal plane of the fluorescence microscope with respect to a reference plane in the integral apparatus; obtaining an image of the fluorescent entity in the sample using the fluorescence microscope; determining a position of the fluorescent entity with respect to a focal plane of the fluorescence microscope, by evaluation of a degree of astigmatism and/or an ellipticity of a fluorescence intensity profile of the image of the fluorescent entity; and micromachining the sample around the determined position using a charged particle beam.

### BACKGROUND

The invention relates to a method for localizing a region of interest in a sample and micromachining the sample using a charged particle beam, preferably a Focused Ion Beam (FIB). In particular, the localizing of the region of interest in the sample according to the invention is performed on a sample for micromachining the sample by means of cryogenic focused ion beam milling to produce samples suitable for inspection in a charged particle beam inspection apparatus, for example an electron microscope.

WO 2022/015163 describes an apparatus and a method for micromachining samples using a FIB. The apparatus comprises an integral combination of: a sample holder, a FIB exposure system for projecting a FIB onto a first position on the sample, and a light optical microscope. The region of interest can be identified and monitored by using fluorescent labels, which can be observed by the light optical microscope, also denoted as a fluorescence microscope.

The micromachining of a sample by means of a FIB can be used, for example, for the manufacturing of lamella (thin slices) of the sample, which are typically imaged using a Transmission Electron Microscope (TEM). The lamella to be milled in the sample is located somewhere in the volume of the sample, and in order to machine the sample such that the region of interest is at least partially located in the lamella.

### SUMMARY OF THE INVENTION

While fluorescence microscopy can provide a high localization accuracy in the optical image plane by fitting the 2D fluorescence intensity profile with a Gaussian function or a previously established microscope Point Spread Function (PSF), the fluorescence microscopy resolution and thereby also localization accuracy is severely limited in the on-axis direction (in a direction parallel to the optical axis of the fluorescence microscope). Moreover, to obtain a localization along the on-axis direction would require the acquisition of a series of images focusing around the object of interest, which requires time and makes the fluorescent entity prone to bleaching.

It is an object of the present invention to more accurately determine the on-axis position of a region of interest inside a sample.

According to a first aspect, the present invention relates to a method for localization of a region of interest inside a sample and for micromachining said sample in an integral fluorescence microscope/charged particle beam apparatus, wherein the region of interest comprises a fluorescent entity, wherein the optics of the fluorescence microscope for imaging the sample onto a detector comprises an astigmatic optical component, wherein the method comprises the steps of:
determine a position of a focal plane of the fluorescence microscope with respect to a reference plane in the integral fluorescence microscope/charged particle beam apparatus;
obtaining an image of the fluorescent entity in the sample using the fluorescence microscope, wherein the image is recorded with an induced astigmatism;
determine a position of the fluorescent entity with respect to a focal plane of the fluorescence microscope and thereby to the reference plane, by evaluation of a degree of astigmatism
and/or an ellipticity of a fluorescence intensity profile of the image of the fluorescent entity due to the astigmatism of the astigmatic optical component; and
micromachining the sample using a charged particle beam for manufacturing a lamella, wherein the determined position of the fluorescent entity is located inside said lamella.

The method of the present invention uses an astigmatic projection system. Due to the astigmatic projection system, a point light source in the sample is converted into an astigmatic image which comprises an elliptical intensity profile that changes along the optical axis of the astigmatic projection system. When the light of a point light source traverses the astigmatic projection system, the astigmatic image changes along the optical axis from a circular cross-section, then it gradually becomes an elliptical cross-section with the major axis in a sagittal plane, until at the primary image, the elliptical cross-section degenerates into a line. Beyond this point the cross-section of the beam opens out to a circle of least confusion. Moving further from the astigmatic projection system, the cross-section of the beam again deforms into a line, called the secondary image, and subsequently becomes an elliptical cross-section again but now with the major axis in a meridional plane.

Accordingly, with a certain degree of astigmatism of the optics of the fluorescence microscope for imaging the sample onto a detector, an observed ellipticity of the intensity profile can be related to the distance of the fluorescent entity from the focal plane. This allows to obtain an accurate position of the fluorescent entity in a direction along the optical axis. Together with the high localization accuracy in the optical image plane, the method of the invention allows to determine the (x, y, z) position of the fluorescent entity with high accuracy, in particular with an accuracy smaller than 50 nm, and thereby the (x, y, z) position of the region of interest for micromachining the sample with reference to the reference plane so as to keep a part of the sample at the determined position inside the lamella.

In an embodiment, the reference plane is a plane containing the coincidence point of the charged particle beam and light optical beams. Preferably, the light optical beams comprises a light beam from the fluorescence microscope for illuminating the sample. By using the coincidence point, the reference plane can be defined and related to both the position of the charged particle beam and the field of view of the fluorescence microscope. This also allows to use the fluorescence microscope for monitoring the progress of the micromachining of the charged particle beam.

In an embodiment, the degree of astigmatism of the astigmatic optical component is adjustable before or during the method steps as described above. As the degree of astigmatism determines both the range along the optical axis over which a fluorescent entity can be measured and the accuracy with which the position is determined, the method according to this embodiment comprises the step of adjusting the degree of astigmatism of the astigmatic optical component. For example, when the degree of astigmatism of the astigmatic optical component is low, the range along the optical axis is large, but the accuracy with which the position is determined is low. When the degree of astigmatism of the astigmatic optical component is high, the accuracy with which the position is determined is high, but the range along the optical path is small. In an embodiment, the astigmatism of the astigmatic optical component is in a range from 50 to 300 mλ.

In an embodiment, the astigmatic optical component comprises a set of cylindrical lenses, wherein the cylindrical lenses are rotatable, wherein the method comprises the step of adjusting the degree of astigmatism by rotating at least one of the cylindrical lenses of said set of cylindrical lenses with respect to the other. Although, a light optical microscope with a set of cylindrical lenses is also disclosed in WO 2022/015163, this set of cylindrical lenses are used to improve the resolution, for example by minimizing aberrations like astigmatism of the optical system of the light optical microscope. However, in the method of the present invention, the set of cylindrical lenses are used for deliberately providing and adjusting a certain amount of astigmatism, and using this astigmatism for localizing the position of the fluorescent entity in the sample.

In an embodiment, the method comprises the step of adjusting the degree of astigmatism of the astigmatic optical component based on the depth of the focal plane of the fluorescence microscope with respect to a surface of the sample, preferably wherein the degree of astigmatism is adjusted to maintain a preferred degree of astigmatism in the fluorescence imaging. For a set degree of astigmatism in the optical imaging path, the actual degree of astigmatism in the measurement may also depend on the depth of the focal plane in the sample due to the refractive index difference between the sample and its environment. The method step of this embodiment proposes to adjust the degree of astigmatism in the imaging path depending on the depth in the sample where the fluorescent entity is located, in order to maintain the optimized degree of astigmatism in the measurement.

It is noted that the depth of the focal plane in the sample can be extracted from a movement of the optical focus and a difference of the refractive index of the sample and its surrounding.

In an embodiment, the method comprises the step of performing a first astigmatic localization using a first degree of astigmatism in the optical system of the fluorescence microscope, and based on this first localization, adjust the astigmatism of the optical system of the fluorescence microscope to a second degree of astigmatism and performing a second astigmatic localization using this second degree of astigmatism to obtain a more precise localization at the anticipated position of the fluorescent entity as determined from the first measurement. Preferably, the second degree of astigmatism is higher than the first degree of astigmatism. In an embodiment, the above described step can be repeated until a predetermined localization accuracy has been reached, preferably a localization accuracy smaller than 50 nm.

It is noted, that in a sample used for micromachining lamella for TEM inspection, the fluorescent entities, such as fluorescent molecules, are inherently fixed in their orientation, either chemically or by cryo-fixation (vitrification). This provides an additional challenge for location determination of a fluorescent entity using the astigmatism of the optical system of the fluorescence microscope. When the orientation of the fluorescent entity is fixed with respect to the optical axis of the fluorescence microscope, the Point Spread Function (PSF) is orientation dependent, especially for the high Numerical Apertures (NA) typically used for localization, but also for intermediate range NA in a range of 0.75-1.0. Thus the 2D images do not show standard Gaussian profiles anymore for fluorescent entities where the emitting dipole has an orientation that is out-of-plane. In other words, when the orientation has at least a vector component parallel to the optical axis of the fluorescence microscope. The inventors have realized that this may lead to significant errors (more than 100 nm) in the localization of the fluorescent entity when using Gaussian models, which would make an astigmatic localization to inaccurate for manufacturing a lamella with a thickness smaller than 1 micrometer, preferably in a range of 100 nm, with the fluorescent entity inside said lamella.

In addition, the collection efficiency of the objective lens is different for fluorescent entities with a larger out-of-plane component (in-plane is the situation where the fluorescent entity is located in a plane parallel to the focal plane of the fluorescence microscope). Accordingly, for a specific observation time at a specific illumination power, the number of photons collected per fluorescent entity varies depending on the out-of-plane orientation of the fluorescent entity.

Both effects mentioned above may lead to a decrease in localization accuracy depending on the orientation of the fluorescent entity. In order to at least substantially prevent this problem, the inventors propose the following further method steps, which should be performed prior to the step of micromachining the sample for manufacturing a lamella.

In an embodiment, the method comprises the steps of: evaluate the out-of-plane orientation of a dipole of the fluorescent entity based on the observed intensity profile and/or determine a signal to background ratio of the fluorescent intensity; if the orientation is largely out-of-plane and/or the signal to background ratio is too low, the specific fluorescent entity and the region of interest around this specific fluorescent entity is discarded; if the orientation is largely in-plane and/or the signal to background is larger than a predetermined value, then proceed with the step to determine the position of the fluorescent entity as described above.

For example, an out-of-plane orientation with a polar angle of 60 degrees or larger is mostly too large for an accurate astigmatic localization. The observed intensity profile of fluorescent entities with an out-of-plane orientation with a polar angle of 45 degrees or smaller and close to the focal plane (for example within a few hundred nanometers), can be localized using Gaussian models with sufficient localization accuracy.

In an embodiment, the evaluation of the out-of-plane orientation of the dipole of the fluorescent entity comprises a comparison of the observed intensity profile with intensity profiles of fluorescent entities with various out-of-plane orientations in a database.

These additional steps are preferably performed prior to actually starting the micromachining of the sample, and allow to select a region of interest of which the location can be establish with sufficient accuracy to have a high probability, or even a certainty, that the region of interest is at least partially inside the lamella. If the signal to background ratio is too low and/or the out-of-plane orientation of the fluorescent entity is too high for sufficient localization accuracy, preferably an accuracy smaller than 50 nm in x, y, and z, this particular fluorescent entity and the corresponding region of interest can be directly discarded as a candidate for micromachining a lamella.

According to a second aspect, the present invention pertains to a method for localization of a region of interest inside a sample and for micromachining said sample in an integral fluorescence microscope/charged particle beam apparatus, wherein the region of interest comprises a fluorescent entity, wherein the optics of the fluorescence microscope for imaging the sample onto a detector comprises an astigmatic optical component, wherein the method comprises the steps of:
determine a position of a focal plane of the fluorescence microscope with respect to a reference plane in the integral fluorescence microscope/charged particle beam apparatus;
obtaining an image of the fluorescent entity in the sample using the fluorescence microscope, wherein the image is recorded with an induced astigmatism;
determine a position of the fluorescent entity with respect to a focal plane of the fluorescence microscope and thereby to the reference plane, and an out-of-plane orientation of the fluorescent entity with respect to a plane parallel to the focal plane by performing a full vectorial fit of the observed intensity profile; and
if the position of the fluorescent entity is determined with a sufficient small accuracy, preferably smaller than 50 nm, micromachining the sample using a charged particle beam for manufacturing a lamella, wherein the determined position of the fluorescent entity is located inside said lamella.

An example of such a full vectorial fit is described in Hulleman et al., Nature Communications 12 (1), (2020). It is noted that Hulleman discloses the use of a vortex wave plate in the optical path and a vectorial fit of the observed intensity profile to get full information on the orientation of a light emitting dipole. In contrast, the present invention does not use a vortex wave plate, but an induced astigmatism. The inventors have found that substantially the same calculations as used by Hulleman can also be used for a vectorial fit of the observed intensity profile with the induced astigmatism. It may be that in this approach, the localization accuracy for any fluorescent entity, irrespective of its orientation, is sufficient, for example if the signal to background ratio is large enough. However, the decreased collection efficiency of the objective lens for fluorescent entities with a larger out-of-plane component may cause the signal to background ratio for out-of-plane oriented fluorescent entities to be too low for sufficient localization accuracy (smaller than 50 nm in x, y and z), in which case the retrieved orientation can be directly used to discard fluorescent entities and the corresponding regions of interest.

An additional advantage of retrieving the orientation of the fluorescent entity, in particular when the fluorescent entity is a molecule, is that the orientation may also be used as input for a final molecular reconstruction after an electron cryo-tomography of the lamella.

According to a third aspect, the present invention pertains to an apparatus for localization of a region of interest inside a sample and for micromachining said sample, wherein the apparatus comprises an integral combination of:
a sample holder for holding the sample,
a charged particle beam exposure system comprising an assembly for projecting a charged particle beam onto a first position where, in use, the charged particle beam impinges on the sample held by the sample holder,
a fluorescence microscope, wherein the fluorescence microscope is configured for imaging or monitoring said sample, wherein the fluorescence microscope comprises optics for imaging the sample onto a detector, wherein said optics comprise an astigmatic optical component, and
a controller which is configured for controlling the apparatus to perform, in use, the steps of the method or an embodiment thereof as described above.

In an embodiment, the optics comprises a cylindrical lens, wherein the cylindrical lens is preferably arranged in a light optical path towards a detector of the fluorescence microscope. A cylindrical lens provides a simple way of introducing a fixed astigmatism in the optical path of the fluorescence microscope.

In an embodiment, the cylindrical lens is a first cylindrical lens, wherein the optics of the fluorescence microscope comprises a second cylindrical lens which is arranged adjacent to the first cylindrical lens, wherein the first and/or second cylindrical lenses are rotatable around a rotation axis which is arranged on the optical axis at the position of the cylindrical lenses on the light optical path towards the detector, and wherein a cylinder axis of the second cylindrical lens is arranged at an angle θ with respect to the cylinder axis of the first cylindrical lens, wherein the angle θ is defined in a plane perpendicular to the optical axis of the light optical path towards the detector. By providing a set of two cylindrical lenses the orientation of the astigmatism and the degree of astigmatism in the optical path of the fluorescence microscope can be adjusted.

In an embodiment of the method or of the apparatus of the invention, the charged particle apparatus comprises a Focused Ion Beam (FIB) apparatus.

The various aspects and features described and shown in the specification can be applied, individually, wherever possible. These individual aspects, in particular the aspects and features described in the attached dependent claims, can be made subject of divisional patent applications.

### BRIEF DESCRIPTION OF THE DRAWINGS

The invention will be elucidated on the basis of an exemplary embodiment shown in the attached drawings, in which:

FIG. 1 schematically shows an example of an integral fluorescence microscope/focused ion beam apparatus,

FIG. 2 schematically shows a flow diagram of a first example of a method according to the invention,

FIG. 3 schematically shows the phenomenon of astigmatism,

FIG. 4 (a) shows examples of out-of-plane orientation dependent 2D intensity profiles as a function of the polar angle θ without an induced astigmatism, and (b) as a function of the distance Z from the focal plane with an induced astigmatism,

FIG. 5 schematically shows a flow diagram of a second example of a method according to the invention,

FIG. 6 schematically shows an example of the localization accuracy in x, y and z versus dipole position along the optical axis, wherein Z=0 is the focal plane, and

FIG. 7 schematically shows an example of the localization accuracy in x, y and z versus dipole orientation with respect to the optical axis, wherein 0 or 180 degrees is parallel to the optical axis and 90 degrees is perpendicular to the optical axis.

### DETAILED DESCRIPTION OF THE INVENTION

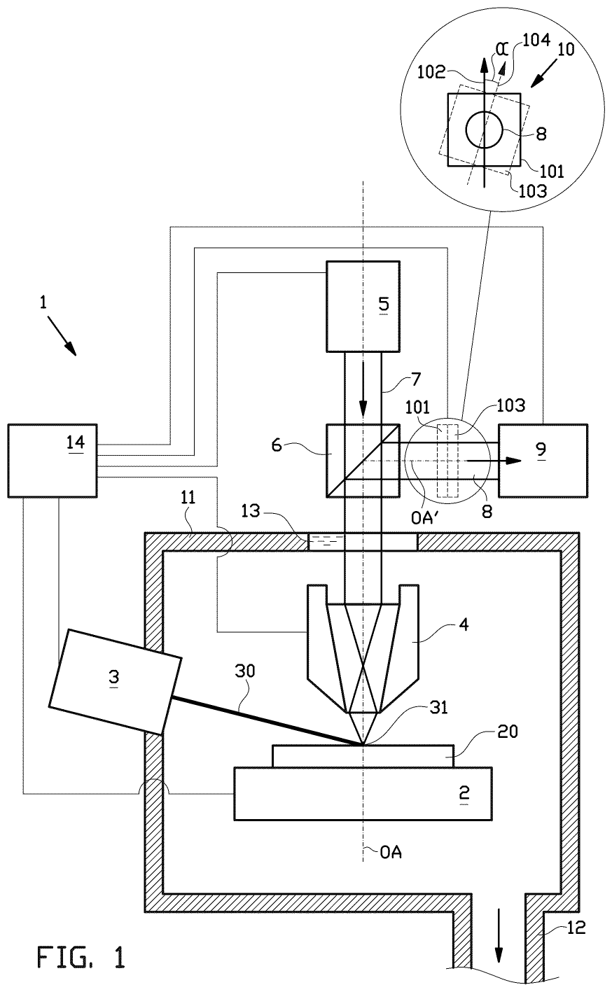

FIG. 1 schematically shows a first exemplary embodiment of an apparatus 1 for localization of a region of interest inside a sample 20 and for micromachining said sample 20. The apparatus comprises an integral combination of:

A sample holder 2 for holding the sample 20;

A charged particle beam exposure system 30 comprising an assembly for projecting a charged particle beam 30 onto a first position 31 where, in use, the charged particle beam 30 impinges on the sample 20 held by the sample holder 2;

A fluorescence microscope, in particular comprising a light source 5, a microscope objective 4 and a detector 9. The fluorescence microscope is configured for imaging or monitoring said sample 20, wherein the fluorescence microscope comprises optics for imaging the sample onto a detector. Said optics comprises the microscope objective 4, a beam-splitter or dichroic mirror 6, and wherein said optics comprise an astigmatic optical component 10; and A controller (14) which is configured for controlling the apparatus to perform, in use, the steps of the method or an embodiment thereof as described above.

More in detail, the fluorescence microscope comprises the objective lens 4, the light source 5 and the detector 9. The light source 5 is configured to direct light 7 along the optical axis OA towards the objective lens 4, which is configured to focus the light onto the sample 20 on the sample holder 2. The beam-splitter or dichroic mirror 6 is arranged in the beam path in between the light source 5 and the objective lens 4, and is configured to pass at least part of the light 7 from the light source 5 towards the objective lens 4 to illuminate the sample 20. The objective lens 4 is furthermore configured to collect light coming from the sample 20. The light collected by the objective lens 4 is at least partially reflected by the half transparent mirror or dichroic mirror 6 to direct said collected light 8 towards the detector 9.

In particular, the light source 5 is configured for emitting light suitable for the excitation of a fluorescent entity in the sample 20, and the detector 9 is configured for detecting and imaging the fluorescence light from the fluorescent entity in the sample 20. Accordingly, the fluorescence microscope is configured for observing the sample 20 on the sample holder 2, and in particular for imaging the sample and a fluorescent entity present in the sample.

As schematically shown in FIG. 1, the charged particle beam exposure system 3 is configured to project a focused charged particle beam 30, preferably a focused ion beam, onto the surface of the sample 20 on the sample holder 2. Preferably, the beam spot size and/or the beam current of the focused charged particle beam 30 are configured so that the focused charged particle beam 30 can remove material from the surface of the sample 20, and thus can micro-machine the sample 20.

The focused charged particle beam exposure system 3 is typically arranged inside a vacuum chamber 11 which is connected to a vacuum pump via a connector 12. The sample holder 2 and the microscope objective 4 are also arranged inside the vacuum chamber 11. Also the other parts of the fluorescence microscope may be arranged inside the vacuum chamber 11, but preferably at least the light source 5 and the detector 9 are arranged in an illumination and detection part, outside the vacuum chamber 11. The vacuum chamber 11 is provided with an optical window 13 which is arranged in the light beam path between the half transparent mirror or dichroic mirror 6 and the microscope objective 4. Due to the illumination and detection part outside the vacuum chamber 11, the light source and the detector 9 do not have to be vacuum-proof.

The apparatus as shown in FIG. 1 is also known from WO 2022/015163. However, in contrast with the apparatus as described in WO 2022/015163, the fluorescence microscope of this example is provided with a cylinder lens arrangement 10 arranged in the light optical path 8 towards the detector 9 of the fluorescence microscope, to purposefully provide a certain degree or amount of astigmatism, preferably and adjustable degree or amount of astigmatism, in order to accurately determine the location of a fluorescent entity in the sample 20 by means of astigmatic localization.

The cylinder lens arrangement 10 comprises, a first cylindrical lens 101 and a second cylindrical lens which is arranged adjacent to the first cylindrical lens 103, wherein the first and/or second cylindrical lenses are rotatable around a rotation axis which is arranged on the optical axis OA′ at the position of the cylindrical lenses on the light optical path towards the detector, and wherein a cylinder axis 104 of the second cylindrical lens 103 is arranged at an angle α with respect to the cylinder axis 102 of the first cylindrical lens 101. The angle α is defined in a plane perpendicular to the optical axis OA′ of the light optical path towards the detector 9. By providing a set of two cylindrical lenses 10 the orientation of the astigmatism and the degree of astigmatism in the optical path of the fluorescence microscope can be adjusted.

The apparatus 1 is in particular suitable for the production of samples used for electron cryo-tomography. Electron Cryo-Tomography (ECT) is a unique technique used for structural biology and its application in e.g. pharmaceutical research as it allows to retrieve macromolecular biological structures at almost atomic resolution. Information at this level is crucial to determine how macromolecules such as proteins and viruses interact during life and disease and how we can intervene in these interactions in order to find ways to cure diseases. As samples for ECT are often kept at cryogenic temperature, the native biological state can be preserved, provided that the sample is rapidly cooled (or fixated) into an amorphous, vitrified state. Native state preservation is of course very important for the interpretation and use of ECT results.

A challenge arises as samples for ECT need to be substantially thin (<1 μm, preferably˜100 nm). This is because contrast in ECT is obtained from phase differences in the electron wave induced by variations in sample composition. Inelastic electron scattering thus has to be circumvented, which means that the samples typically need to be thinner than the mean free path for inelastic scattering. In practice, a sample thickness between 100-200 nm is preferred and thinner is often better. An additional reason to aim for thinner samples is that for thinner samples, a lower electron beam energy may be used, mitigating sample damage and thereby allowing to extract more information at higher resolution from the sample. Relevant biological materials however are mostly not this thin (say, 200-300 nm for the smallest bacterial cells, tens of um or more for human cells, and even thicker for clusters of cells, tissues, organoids, etc.).

Cryogenic Focused Ion Beam (FIB) milling provides a solution to this problem as the focused ion beam allows to mill away material at high resolution (˜10 nm) without affecting the unexposed material. Thus a thin slice or lamella can be cut out of a cryo-fixed biological material after which (part of) this lamella can be reconstructed at almost atomic resolution using ECT. Automated workflows for cryo-FIB of biological materials have recently been developed. However, a problem with cryo-FIB milling of biological materials is that this is a ‘blind’ process meaning one can only image the outer surface of the biological sample with the ion beam or with an electron beam in a combined Focused Ion Beam—Scanning Electron Microscope (FIB-SEM). Biological materials do not provide contrast in FIB or SEM to reveal compositional differences.

A solution to this problem (finding the regions of interest for FIB milling) may be found by correlating the FIB-milling to cryogenic fluorescence microscope (cryo-FM) data obtained from the same cryo-fixed sample (so-called cryo-CLEM). This can in principle be done in the apparatus of WO 2022/015163 and in the apparatus of FIG. 1.

In a further development, FM and cryo-FIB-SEM may even be combined such that all three beams (photons, ions, and electrons) are coincident. In this way FM and SEM can be conducted with the sample in the right position for FIB-milling. This approach naturally mitigates repositioning errors, while also allows for live monitoring of the FIB-milling by means of light microscopy.

It should be noted that the lamella to be milled in the sample is located somewhere in the volume of the sample. While FM can permit sufficiently high localization accuracy (<50 nm) in the optical image plane by fitting the 2D fluorescence intensity profile with a Gaussian function or a previously established microscope Point Spread Function (PSF), FM resolution and thereby also localization accuracy is severely limited in the on-axis direction. Moreover, to obtain a localization along the on-axis direction would require the acquisition of a series of images focusing around the object of interest, which requires time and makes the fluorescent entity prone to bleaching.

In the method of the present invention an astigmatic projection system is used to obtain a sufficiently high localization accuracy along the direction of the optical axis of the FM, as the observed ellipticity of the lateral 2D intensity profile due to astigmatism can be related to the distance of the fluorescent entity from the focal plane.

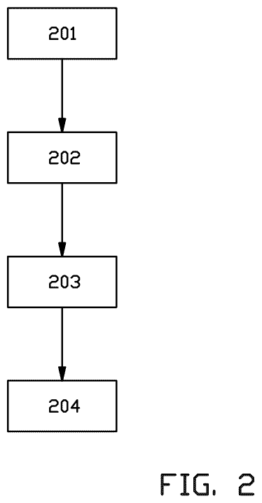

In a first example, as schematically shown in FIG. 2, the method for localization of a region of interest inside a sample 20 and for micromachining said sample in an integral fluorescence microscope/charged particle beam apparatus 1, wherein the region of interest comprises a fluorescent entity, and wherein the optics of the fluorescence microscope for imaging the sample 20 onto a detector 9 comprises an astigmatic optical component 10, comprises the steps of:
201 determine a position of a focal plane of the fluorescence microscope with respect to a reference plane in the integral fluorescence microscope/charged particle beam apparatus 1;
202 obtaining an image of the fluorescent entity in the sample 20 using the fluorescence microscope, wherein the image is recorded with an induced astigmatism;
203 determine a position of the fluorescent entity with respect to a focal plane of the fluorescence microscope and thereby to the reference plane, by evaluation of a degree of astigmatism and/or an ellipticity of a fluorescence intensity profile of the image of the fluorescent entity due to the astigmatism of the astigmatic optical component 10; and
204 micromachining the sample 20 using the FIB 30 for manufacturing a lamella, wherein the determined position of the fluorescent entity is located inside said lamella.

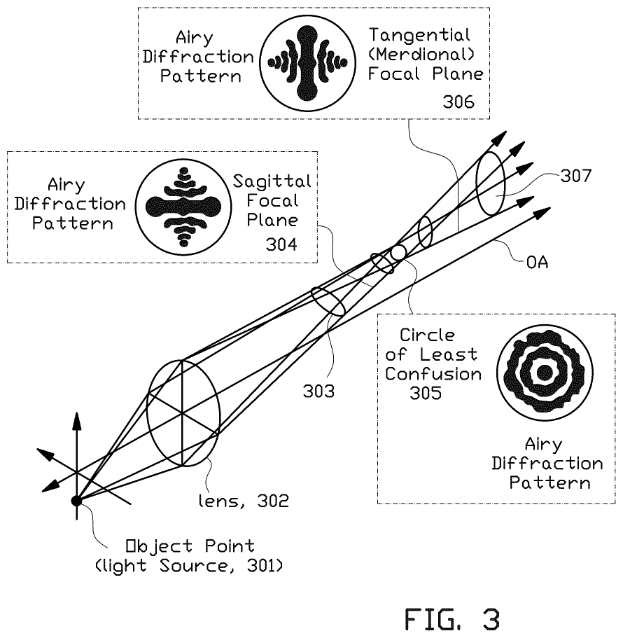

As schematically shown in FIG. 3, the method of astigmatic localization may be used to determine the (x, y, z) position of the fluorescent entity (hereafter called molecule) from a single image and thereby the (x, y, z) position of the region of interest for milling the lamella. Due to the astigmatic projection system with the lens 302, a point light source 301 in the sample is converted into an astigmatic image which comprises an elliptical intensity profile 303 that changes along the optical axis OA of the astigmatic projection system. When the light of a point light source 301 traverses the astigmatic lens 302, the astigmatic image changes along the optical axis OA from a circular cross-section near the lens 302, then it gradually becomes an elliptical cross-section 303 with the major axis in a sagittal plane, until at the primary image 304, the elliptical cross-section degenerates into a line. Beyond this point the cross-section of the beam opens out to a circle of least confusion 305. Moving further from the astigmatic projection system, the cross-section of the beam again deforms into a line, called the secondary image 306, and subsequently becomes an elliptical cross-section 307 again but now with the major axis in a meridional plane.

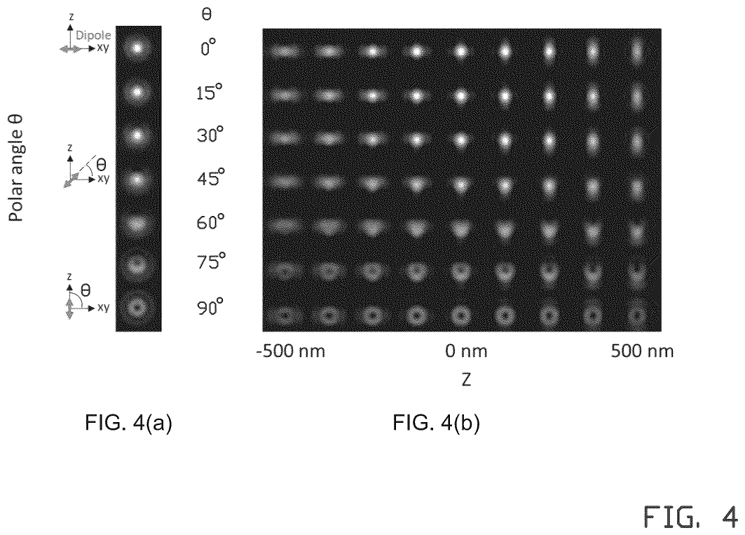

However using astigmatic imaging to determine the position of the fluorescent entity also provides a few challenges. Some of these relate to the fact that fluorescent entities may have a fixed dipole orientation associated with the emission of light. This is particularly the case for a (single) molecule, which is why in the following we will refer to fluorescent entities as molecules, but it may also hold for larger assemblies like quantum dots or clusters of mutually aligned molecules (e.g. J-aggregates, molecules in a membrane):
(1) Astigmatic localization is typically done in room-temperature experiments where molecules are free to diffuse or rotate. Typically a high numerical aperture lens is used to collect the most photons and have the highest image resolution which translates to the highest possible localization accuracy. However, a fluorescent molecule in a sample for FIB-SEM is inherently fixed, either chemically or by cryo-fixation (vitrification). Thus the orientation of the molecule is fixed with respect to the optical axis, which means that the PSF is orientation dependent, especially for the high numerical apertures (NA=1-1.4), typically used for localization, but also for intermediate range NA=0.75-1. Thus the 2D images do not show standard Gaussian profiles anymore for molecules that have an orientation that is out-of-plane, as for example shown in FIG. 4. This leads to significant errors (>100 nm) in the localization when using Gaussian models.
(2) In addition to point (1), the collection efficiency of the objective lens is different for molecules with a larger out-of-plane component. This means that for a specific observation time at a specific illumination power, the number of photons collected per molecule varies depending on the molecular orientation. Both effects (1) and (2) may lead to varying localization accuracy depending on molecular orientation.
(3) With astigmatic imaging, the position of the molecule is determined with respect to the focal plane. One wants to do only a few measurements, preferably a single measurement, to avoid exposure of the cryogenic sample to light (heating, fluorescence bleaching) and to allow for a fast measurement (minimizing drift of the FM-FIB-SEM alignment). The degree of astigmatism determines both the range (along the optical axis) over which molecules can be measured and the accuracy with which the position is determined. It may thus be preferred to work with an optimized degree of astigmatism.
(4) For a set degree of astigmatism in the optical imaging path, the actual degree of astigmatism in the measurement may depend on the depth of the focal plane in the sample, due to the refractive index difference between (vitreous) sample and vacuum. Thus it may be needed to adjust the degree of astigmatism in the imaging path depending on the depth in the sample in order to maintain the optimized degree of astigmatism in the measurement.

The present invention and the embodiments thereof aim to accommodate for these effects. For points (3) and (4) it means that it is advantageous to be able to set the degree of astigmatism to a preferred range and adjust that degree based upon height in the sample (which can be extracted from movement of the optical focus and vacuum-sample refractive index difference). This also allows to adjust the degree of astigmatism after a first measurement to allow for a second, more precise measurement at the anticipated height of the molecule as extracted from the first measurement.

According to an example of the present invention, the out-of-plane orientation of the molecule may be evaluated based on the observed intensity pattern as shown FIG. 4 (a). FIG. 4 (a) shows examples of the intensity patterns for light emitting dipoles with an out-of-plane orientation with a polar angle 0, without astigmatism and with the dipole arranged 500 nm from the focus position. FIG. 4 (b) shows examples of the intensity patterns for light emitting dipoles with an out-of-plane orientation with a polar angle θ and as a function of the distance Z to the focus position, with an induced astigmatism. As shown in these figures, an out-of-plane orientation with a polar angle θ of 60 degrees or larger results in an intensity pattern that deviates from a Gaussian profile to a large extend, making it difficult to obtain an accurate astigmatic localization using Gaussian models. The observed intensity profile of fluorescent entities with an out-of-plane orientation with a polar angle θ of 45 degrees or smaller and close to the focal plane (for example within a few hundred nanometers as shown in FIG. 4 (b)), can be localized using Gaussian models with sufficient localization accuracy.

One can thus use a discriminating feature of the intensity profile, either by (automated) comparison of the profile with respect to a set of profiles like in FIG. 4 (b), or by using a statistical measure calculated on the profile to discard molecules with too large an out-of-plane orientation.

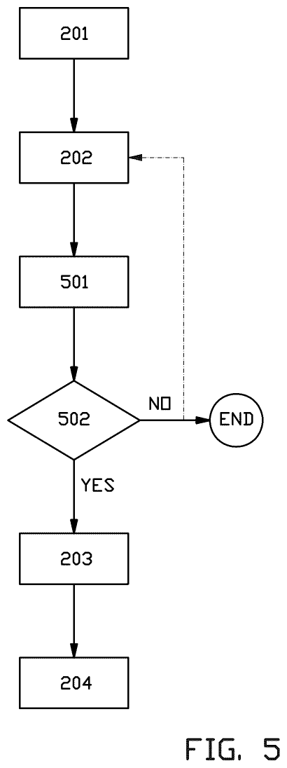

In an second example, as schematically shown in FIG. 5, the method for localization of a region of interest inside a sample 20 and for micromachining said sample in an integral fluorescence microscope/charged particle beam apparatus 1, wherein the region of interest comprises a fluorescent entity, and wherein the optics of the fluorescence microscope for imaging the sample 20 onto a detector 9 comprises an astigmatic optical component 10, comprises the steps of:
201 determine a position of a focal plane of the fluorescence microscope with respect to a reference plane in the integral fluorescence microscope/charged particle beam apparatus 1;
202 obtaining an image of the fluorescent entity in the sample 20 using the fluorescence microscope;
501 evaluate the out-of-plane orientation of a dipole of the fluorescent entity based on the observed intensity profile and/or determine a signal to background ratio of the fluorescent intensity;
502 Is the orientation of the dipole of the fluorescent entity largely in-plane (for example when the polar angle θ is smaller than 60 degrees)? If NO, the specific fluorescent entity and the region of interest around this specific fluorescent entity is discarded. If Yes, then proceed
203 determine a position of the fluorescent entity with respect to a focal plane of the fluorescence microscope and thereby to the reference plane, by evaluation of a degree of astigmatism and/or an ellipticity of a fluorescence intensity profile of the image of the fluorescent entity due to the astigmatism of the astigmatic optical component 10; and
204 micromachining the sample 20 using the FIB 30 for manufacturing a lamella, wherein the determined position of the fluorescent entity is located inside said lamella.

It is noted that when a specific fluorescent entity is discarded in step 502, the method may return 503 to step 202 for obtaining an image of a different fluorescent entity in the sample 20, and proceed with the other steps of the method but now on the basis of the different fluorescent entity.

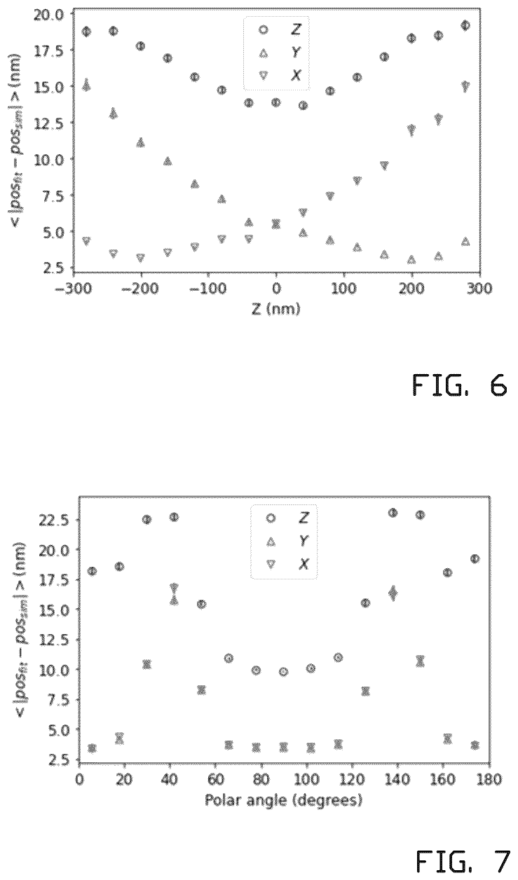

Alternatively, one can perform a full vectorial fit of the intensity profile, instead of a Gaussian fit, to improve the on-axis localization accuracy and retrieve the orientation of the molecule. FIGS. 6 and 7 show an example of the accuracies which can be obtained using a simulation of a single dipole with the orientation and 3D position, where the intensity distribution is fitted with a vectorial PSF (including astigmatism), with a signal to background ratio of 500. From FIG. 6 it is clear that the error in the position of the fluorescent entity is smallest at the focus point (Z=0). From FIG. 7 it is clear that the error in the position of the fluorescent entity is smallest when the dipole orientation is substantially perpendicular to the optical axis (polar angle of 0 or 180 degrees is parallel to the optical axis and 90 degrees is perpendicular to the optical axis).

It is noted that the examples shown in FIGS. 6 and 7 are highly dependent of the Numerical Aperture of the optical system of the fluorescence microscope, the number of photons collected prior to performing the vectorial fit, the background intensity, the degree of astigmatism, etc.

It may be that in this approach, the localization accuracy for any molecule, irrespective of its orientation, is sufficient, e.g. if the signal to background is larger than 40 to 200, which may also depend on the amount of signal photons collected. However, effect (2) mentioned above may cause the signal to background ratio for out-of-plane oriented molecules to be too low for sufficient localization accuracy (<50 nm in x, y, z), in which case the retrieved orientation can be directly used to discard molecules and thereby regions of interest. An additional advantage of retrieving the orientation of the molecule may be that the orientation may be used as prior input/alignment for the final molecular reconstruction after ECT.

The present invention thus allows to approve or reject areas for micromachining a sample based on a localization accuracy, which localization accuracy for astigmatic localization also depends on the orientation of the fluorescent entity when said orientation is fixed either chemically or by cryo-fixation. When the localization accuracy for a certain fluorescent entity is low, the region of interest of this particular fluorescent entity is rejected for milling a lamella, because there is a high likelihood that the specific region of interest does not end up in the lamella and said lamella would therefore be useless for studying the specific region of interest. The invention thus allows to select more promising candidates which provide a high localization accuracy, which provides a high likelihood, or even a certainty, that the region of interest is indeed located inside the lamella.

In summary, the invention relates to a method and apparatus for localization of a region of interest with a fluorescent entity inside a sample and for micromachining said sample in an integral fluorescence microscope/charged particle beam apparatus. The optics of the fluorescence microscope for imaging the sample onto a detector comprises an astigmatic optical component. The method comprises the steps of:

determine a position of a focal plane of the fluorescence microscope with respect to a reference plane in said integral apparatus; obtaining an image of the fluorescent entity in the sample using the fluorescence microscope; determine a position of the fluorescent entity with respect to a focal plane of the fluorescence microscope, by evaluation of a degree of astigmatism and/or an ellipticity of a fluorescence intensity profile of the image of the fluorescent entity; and micromachining the sample around the determined position using a charged particle beam.

It is to be understood that the above description is included to illustrate the operation of the preferred embodiments and is not meant to limit the scope of the invention. From the above discussion, many variations will be apparent to one skilled in the art that would yet be encompassed by the scope of the present invention.

1-15. (canceled)

16. A method for localization of a region of interest inside a sample and for micromachining said sample in an integral fluorescence microscope/charged particle beam apparatus, wherein the region of interest comprises a fluorescent entity, wherein the optics of the fluorescence microscope for imaging the sample onto a detector comprises an astigmatic optical component, the method comprising the steps of:
determining a position of a focal plane of the fluorescence microscope with respect to a reference plane in the integral fluorescence microscope/charged particle beam apparatus;
obtaining an image of the fluorescent entity in the sample using the fluorescence microscope;
determining a position of the fluorescent entity with respect to a focal plane of the fluorescence microscope and thereby to the reference plane, by evaluation of a degree of astigmatism and/or an ellipticity of a fluorescence intensity profile of the image of the fluorescent entity due to the astigmatism of the astigmatic optical component; and
micromachining the sample using a charged particle beam for manufacturing a lamella, wherein the determined position of the fluorescent entity is located inside said lamella.

17. The method according to claim 16, wherein the reference plane is a plane containing the coincidence point of the charged particle beam and light optical beams of the fluorescence microscope.

18. The method according to claim 16, wherein the degree of astigmatism of the astigmatic optical component is adjustable before or during the method steps as described above, preferably wherein the astigmatism of the astigmatic optical component is in a range from 50 to 300 mλ.

19. The method according to claim 18, wherein the astigmatic optical component comprises a set of cylindrical lenses,
wherein the cylindrical lenses are rotatable,
wherein the method comprises the step of adjusting the degree of astigmatism by rotating at least one of the cylindrical lenses of said set of cylindrical lenses with respect to the other.

20. The method according to claim 18, wherein the method further comprises the step of adjusting the degree of astigmatism of the astigmatic optical component based on the depth of the focal plane of the fluorescence microscope with respect to a surface of the sample.

21. The method according to claim 20, wherein the degree of astigmatism is adjusted to maintain a preferred degree of astigmatism in the fluorescence imaging.

22. The method according to claim 18, wherein the method further comprises the step of performing a first astigmatic localization using a first degree of astigmatism in the optical system of the fluorescence microscope, and based on this first localization, adjusting the astigmatism of the optical system of the fluorescence microscope to a second degree of astigmatism and performing a second astigmatic localization using this second degree of astigmatism to obtain a more precise localization at the anticipated position of the fluorescent entity as determined from the first measurement, preferably wherein the second degree of astigmatism is higher than the first degree of astigmatism.

23. The method according to claim 22, wherein the step of performing the first astigmatic localization is repeated until a predetermined localization accuracy has been reached, preferably a localization accuracy smaller than 50 nm.

24. The method according to claim 16, wherein the method further comprises the steps of:
evaluating the out-of-plane orientation of a dipole of the fluorescent entity based on the observed intensity profile and/or determine a signal to background ratio of the fluorescent intensity; and
in a case that the orientation is largely out-of-plane and/or the signal to background ratio is too low, the specific fluorescent entity and the region of interest around this specific fluorescent entity is discarded; and
in a case that the orientation is largely in-plane and/or the signal to background is larger than a predetermined value, proceeding with the step to determine the position of the fluorescent entity.

25. The method according to claim 24, wherein the evaluation of the out-of-plane orientation of the dipole of the fluorescent entity comprises a comparison of the observed intensity profile with intensity profiles of fluorescent entities with various out-of-plane orientations in a database.

26. A method for localization of a region of interest inside a sample and for micromachining said sample in an integral fluorescence microscope/charged particle beam apparatus, wherein the region of interest comprises a fluorescent entity, wherein the optics of the fluorescence microscope for imaging the sample onto a detector comprises an astigmatic optical component, the method comprising the steps of:
determining a position of a focal plane of the fluorescence microscope with respect to a reference plane in the integral fluorescence microscope/charged particle beam apparatus;
obtaining an image of the fluorescent entity in the sample using the fluorescence microscope;
determining a position of the fluorescent entity with respect to a focal plane of the fluorescence microscope and thereby to the reference plane, and an out-of-plane orientation of the fluorescent entity with respect to a plane parallel to the focal plane by performing a full vectorial fit of the observed intensity profile; and
in a case that the position of the fluorescent entity is determined with an accuracy smaller than 50 nm, micromachining the sample using a charged particle beam for manufacturing a lamella, wherein the determined position of the fluorescent entity is located inside said lamella.

27. An apparatus for localization of a region of interest inside a sample and for micromachining said sample, the apparatus comprising an integral combination of:
a sample holder for holding the sample;
a charged particle beam exposure system comprising an assembly for projecting a charged particle beam onto a first position where, in use, the charged particle beam impinges on the sample held by the sample holder;
a fluorescence microscope, wherein the fluorescence microscope is configured for imaging or monitoring said sample, wherein the fluorescence microscope comprises optics for imaging the sample onto a detector, wherein said optics comprise an astigmatic optical component; and
a controller which is configured for controlling the apparatus to perform the steps of the method according to claim 16.

28. The apparatus according to claim 27, wherein the optics comprises a cylindrical lens,
wherein the cylindrical lens is preferably arranged in a light optical path towards a detector of the fluorescence microscope.

29. The apparatus according to claim 28, wherein the cylindrical lens is a first cylindrical lens,
wherein the optics of the fluorescence microscope comprises a second cylindrical lens which is arranged adjacent to the first cylindrical lens,
wherein the first and/or second cylindrical lenses are rotatable around a rotation axis which is arranged on the optical axis at the position of the cylindrical lenses on the light optical path towards the detector, and
wherein a cylinder axis of the second cylindrical lens is arranged at an angle θ with respect to the cylinder axis of the first cylindrical lens,
wherein the angle 0 is defined in a plane perpendicular to the optical axis of the light optical path towards the detector.

30. The method according to claim 16, wherein the charged particle apparatus comprises a Focused Ion Beam (FIB) apparatus.

31. The method according to claim 26, wherein the charged particle apparatus comprises a Focused Ion Beam (FIB) apparatus.

32. The apparatus according to claim 27, wherein the charged particle apparatus comprises a Focused Ion Beam (FIB) apparatus.

33. An apparatus for localization of a region of interest inside a sample and for micromachining said sample, the apparatus comprising an integral combination of:
a sample holder for holding the sample,
a charged particle beam exposure system comprising an assembly for projecting a charged particle beam onto a first position where, in use, the charged particle beam impinges on the sample held by the sample holder,
a fluorescence microscope, wherein the fluorescence microscope is configured for imaging or monitoring said sample, wherein the fluorescence microscope comprises optics for imaging the sample onto a detector, wherein said optics comprise an astigmatic optical component, and
a controller which is configured for controlling the apparatus to perform the steps of the method according to claim 26.
